(19) United States
(12) Patent Application Publication
(10) Pub. No.: US 2026/0066911 A1
(43) Pub. Date: Mar. 5, 2026

(54) SEMICONDUCTOR DEVICE AND CONTROL METHOD THEREOF

(71) Applicant: Renesas Electronics Corporation, Tokyo (JP)

(72) Inventors: Yoichi IIZUKA, Tokyo (JP); Fukashi MORISHITA, Tokyo (JP)

(73) Assignee: Renesas Electronics Corporation, Tokyo (JP)

(21) Appl. No.: 19/312,993

(22) Filed: Aug. 28, 2025

(30) Foreign Application Priority Data
Aug. 30, 2024 (JP) 2024-148072

(51) Int. Cl. H03M 1/08; G06F 3/0354; G06F 3/038

(52) U.S. Cl. CPC H03M 1/08; G06F 3/03545; G06F 3/038

(57) ABSTRACT

A semiconductor device includes a plurality of sample-and-hold circuits that sample voltages of an analog input signal at different timings and respectively hold them as a plurality of input voltages, a ramp signal generation circuit that generates a ramp signal whose potential changes linearly, a counter that triggers a start of the linear change in the ramp signal and perform a counting operation, a plurality of AD conversion circuits that output a count value of the counter at a timing where each of the plurality of input voltages matches the voltage of the ramp signal as a plurality of digital signals corresponding to the plurality of input voltages, and a control circuit that controls a slope of the linear change in the ramp signal and the amount of change in the count value of the counter according to the count value of the counter.

### CROSS-REFERENCE TO RELATED APPLICATION

This application claims priority under 35 U.S. C. § 119 to Japanese Patent Application No. 2024-148072 filed on Aug. 30, 2024. The disclosure of Japanese Patent Application No. 2024-148072, including the specification, drawings and abstract is incorporated herein by reference in its entirety.

### BACKGROUND

The present disclosure relates to a semiconductor device, a control method thereof, and a control program, and relates to, for example, a semiconductor device, a control method thereof, and a control program suitable for reducing circuit size while suppressing quality degradation of AD conversion.

A touch panel or the like is equipped with a semiconductor device that performs AD conversion of analog input signals including sinusoidal signals (pen signals) of a predetermined frequency in which an amplitude increases due to an influence of an antenna coil when a touch pen approaches the touch panel. It is required for such a semiconductor device to have its circuit size reduced while suppressing quality degradation of AD conversion.

There are disclosed techniques listed below.

[Patent Document 1] Japanese Unexamined Patent Application Publication No. 2024-67061

[Non-Patent Document 1] Changbyung Park, et el., “A Pen-Pressure-Sensitive Capacitive Touch System Using Electrically Coupled Resonance Pen”, IEEE JOURNAL OF SOLID-STATE CIRCUITS, VOL. 51, NO. 1, JANUARY 2016.

[Non-Patent Document 2] SangYun Kim, et el., “A 39.5-dB SNR, 300-Hz Frame-Rate, 56×70-Channel Read-Out IC for Electromagnetic Resonance Touch Panels”, IEEE TRANSACTIONS ON INDUSTRIAL ELECTRONICS, VOL. 65, NO. 6, JUNE 2018.

[Non-Patent Document 3] Jun-Eun Park, et el., “A Noise-Immunity-Enhanced Analog Front-End for 36×64 Touch-Screen Controllers With 20-VPP Noise Tolerance at 100 kHz”, IEEE JOURNAL OF SOLID-STATE CIRCUITS, VOL. 54, NO. 5, MAY 2019.

Patent Document 1 and Non-Patent Documents 1 to 3 disclose techniques regarding AD conversion.

### SUMMARY

As described above, it is required for a semiconductor device mounted on a touch panel and the like to have its circuit size reduced while suppressing degradation of AD conversion precision. However, for example, if the number of AD converters that sample the voltages of a certain input signal at different timings and convert them into digital signals is reduced in order to reduce the circuit size, the AD conversion precision of the input signal would be degraded. Other problems and novel features will become clear from the description of the present specification and accompanying drawings.

A semiconductor device according to the present disclosure includes a plurality of sample-and-hold circuits each configured to sample voltages of an analog input signal at different timings and hold them as a plurality of input voltages, a ramp signal generation circuit configured to generate a ramp signal whose potential changes linearly, a counter configured to trigger a start of the linear change in the ramp signal and perform a counting operation, a plurality of comparison circuits each configured to compare each of the plurality of input voltages and a voltage of the ramp signal, a plurality of latch circuits each configured to output a count value of the counter at a timing where each of the plurality of input voltages matches the voltage of the ramp signal as a plurality of digital signals corresponding to the plurality of input voltages, and a control circuit configured to control a slope of the linear change in the ramp signal and the amount of change in the count value of the counter according to the count value of the counter, wherein the plurality of digital signals are output as a result of AD conversion of the input signal.

A control method of a semiconductor device according to the present disclosure includes sampling voltages of an analog input signal at different timings and respectively holding them as a plurality of input voltages, triggering a start of a linear change in a ramp signal whose potential changes linearly and starting a counting operation of a counter, and outputting a count value of the counter at a timing where each of the plurality of input voltages matches a voltage of the ramp signal as a result of AD conversion of the input signal, wherein a slope of the linear change in the ramp signal and the amount of change in the count value of the counter are controlled according to the count value of the counter.

A control program according to the present disclosure configured to cause a computer to execute a process of sampling voltages of an analog input signal at different timings and respectively holding them as a plurality of input voltages, a process of triggering a start of a linear change in a ramp signal whose potential changes linearly and starting a counting operation of a counter, and a process of outputting a count value of the counter at a timing where each of the plurality of input voltages matches a voltage of the ramp signal as a result of AD conversion of the input signal, wherein the control program further causes the computer to execute a process of controlling a slope of the linear change in the ramp signal and the amount of change in the count value of the counter according to the count value of the counter.

The present disclosure can provide a semiconductor device, a control method thereof, and a control program that are capable of reducing the circuit size while suppressing quality degradation of AD conversion.

### BRIEF DESCRIPTION OF THE DRAWINGS

FIG. 1 is a block diagram showing a configuration example of a semiconductor device according to a first embodiment.

FIG. 2 is a block diagram showing a configuration example of a portion of the semiconductor device according to the first embodiment.

FIG. 3 is a drawing showing a configuration example of a ramp signal generation circuit provided in the semiconductor device according to the first embodiment.

FIG. 4 is a drawing showing a configuration example of a counter provided in the semiconductor device according to the first embodiment.

FIG. 5 is a drawing showing an example of control contents of the counter shown in FIG. 4 controlled by a control circuit.

FIG. 6 is a drawing showing an example of setting contents of a register provided in the semiconductor device according to the first embodiment in a high-speed operation mode.

FIG. 7 is a drawing showing signal waveforms for an input signal IN1 and each of the pen signal components contained therein.

FIG. 8 is a flowchart showing an operation of the semiconductor device according to the first embodiment.

FIG. 9 is a timing chart showing an operation of the semiconductor device according to the first embodiment in the high-speed operation mode.

FIG. 10 is a drawing showing a relationship between input voltages and output results in the semiconductor device according to the first embodiment.

FIG. 11 is a drawing showing an example of setting contents of the register provided in the semiconductor device according to the first embodiment in a normal operation mode.

FIG. 12 is a timing chart showing an operation of the semiconductor device according to the first embodiment in the normal operation mode.

FIG. 13 is a timing chart showing another example of an operation of the semiconductor device according to the first embodiment in the high-speed operation mode.

FIG. 14 is a block diagram showing a configuration example of a semiconductor device according to a second embodiment.

FIG. 15 is a block diagram showing a configuration example of a portion of the semiconductor device according to the second embodiment.

### DETAILED DESCRIPTION

The following is a description of embodiments with reference to the drawings. The drawings are simplified and the technical scope of the embodiments therefore should not be interpreted narrowly on the basis of the descriptions of these drawings. In addition, identical elements are denoted by an identical reference sign, and redundant descriptions are omitted as appropriate.

In the embodiments described below, the invention will be described in a plurality of sections or embodiments if necessary for the sake of convenience. However, these sections or embodiments are not irrelevant to each other unless otherwise clearly specified, and one section or embodiment partially or entirely corresponds to another section or embodiment as a modification, detailed or supplementary description or the like. In addition, in the embodiments described below, when referring to the number of a component (including number of pieces, numerical value, amount and range), the number is not limited to a specified number and may be less than or greater than this number unless otherwise clearly specified or unless it is obvious from the context that the number is limited to the specified number in principle. Furthermore, in the embodiments described below, each component (including an operational step or the like) is not indispensable unless otherwise clearly specified or unless it is obvious from the context that the component is indispensable in principle. Likewise, in the embodiments described below, when referring to a shape, a positional relation or the like of a component, a substantially approximate shape, a similar shape or the like is included unless otherwise clearly specified or unless it is obvious from the context that the shape, the positional relation or the like of the component differs in principle. The same applies to the above-described number (including number of pieces, numerical value, amount and range).

### First Embodiment

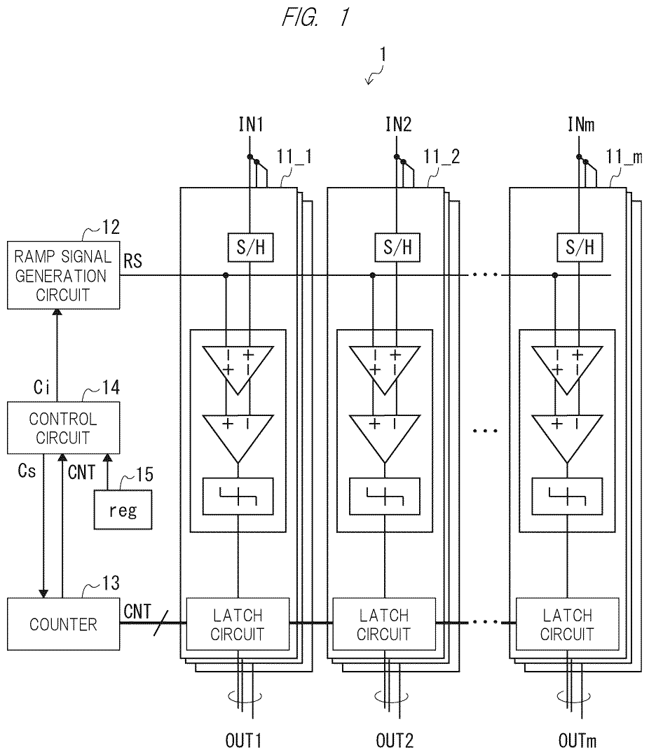

FIG. 1 is a block diagram showing a configuration example of a semiconductor device 1 according to a first embodiment. The semiconductor device 1 is a device mounted in, for example, a touch panel, and is configured to perform AD conversion on analog input signals including sinusoidal signals (hereinafter also referred to as “pen signals”) of a predetermined frequency in which an amplitude increases due to an antenna coil when a touch pen approaches the touch panel.

As shown in FIG. 1, the semiconductor device 1 comprises an m number (m being an integer of two or more) of AD converters 11_1 to 11_m, a ramp signal generation circuit 12, a counter 13, a control circuit 14, and a register (reg) 15. The register 15 may be built into the control circuit 14.

The AD converters 11_1 to 11_m each perform AD conversion of different analog input signals IN1 to INm. Each of the AD converters 11_1 to 11_m is configured by an n number (n being an integer of two or more) of AD conversion circuits.

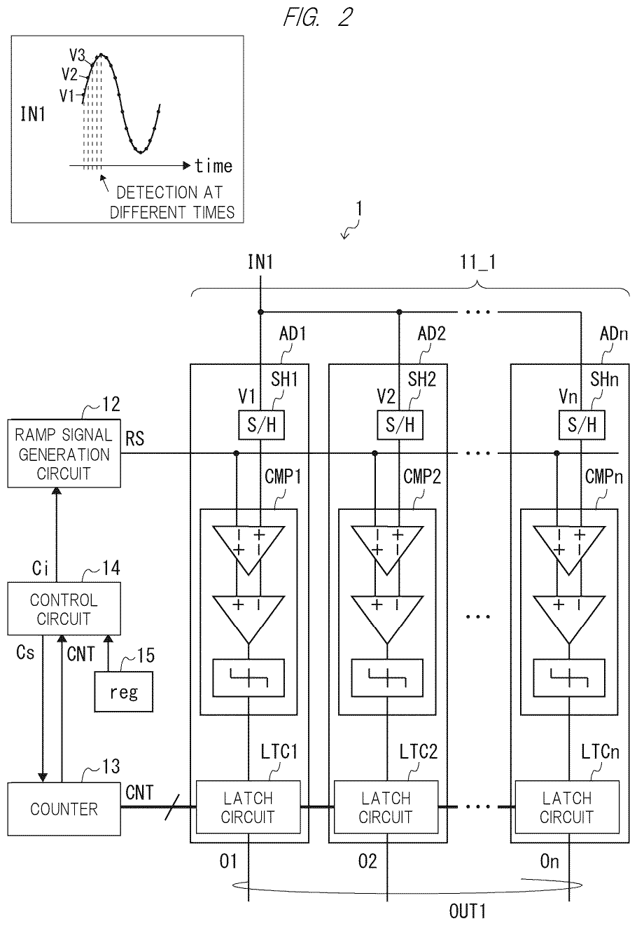

FIG. 2 is a block diagram showing a configuration example of a portion of the semiconductor device 1. The example of FIG. 2 shows a configuration example of the AD converter 11_1 among the AD converters 11_1 to 11_m. The AD converter 11_1 is configured by an n number of AD conversion circuits AD1 to ADn. The AD converters 11_2 to 11_m have similar configurations as the AD converter 11_1 with the exception of the input signals IN2 to INm being respectively input instead of the input signal IN1, and thus, descriptions thereof are omitted as appropriate.

The AD conversion circuit AD1 comprises a sample-and-hold circuit SH1, a comparison circuit CMP1, and a latch circuit LTC1. The AD conversion circuit AD2 comprises a sample-and-hold circuit SH2, a comparison circuit CMP2, and a latch circuit LTC2. Likewise, the AD conversion circuit ADn comprises a sample-and-hold circuit SHn, a comparison circuit CMPn, and a latch circuit LTCn.

The ramp signal generation circuit 12 generates a ramp signal RS whose potential changes linearly. The counter 13 triggers a start of a linear change in the ramp signal RS and synchronizes with a rising edge of a clock signal CLK to perform a counting operation. The control circuit 14 controls a slope of the linear change in the ramp signal RS and the amount of change in a count value of the counter 13 (count value that increases per count-up operation of the counter 13) based on digital codes Ci and Cs extracted from the register 15 according to the count value of the counter 13.

The sample-and-hold circuits SH1 to SHn each sample voltages of the analog input signal IN1 at different timings and hold them as input voltages V1 to Vn.

The comparison circuits CMP1 to CMPn compare each of the input voltages V1 to Vn and a voltage of the ramp signal RS whose potential changes linearly. Note that the comparison circuits CMP1 to CMPn start the comparison when the potential of the ramp signal RS starts to change linearly and when the counter 13 starts the counting operation.

The latch circuits LTC1 to LTCn each output a count value of the counter 13 at a timing where each of the input voltages V1 to Vn matches the voltage of the ramp signal RS as a plurality of digital signals O1 to On respectively corresponding to the input voltages V1 to Vn.

The AD converter 11_1 outputs these digital signals O1 to On as a result OUT1 of AD conversion of the input signal IN1. Likewise, the AD converter 11_2 outputs a result OUT2 of AD conversion of the input signal IN2. The AD converter 11_m outputs a result OUTm of AD conversion of the input signal INm.

### Configuration Example of Ramp Signal Generation Circuit 12

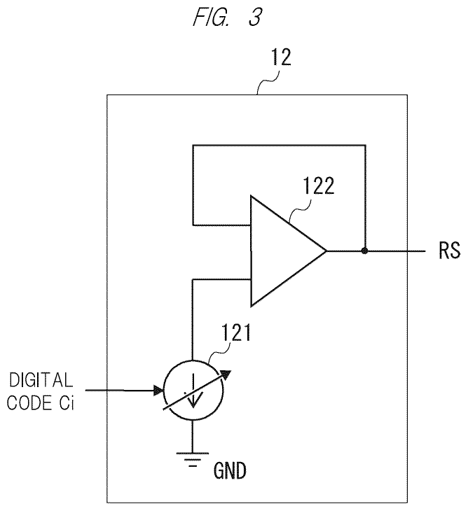

FIG. 3 is a drawing showing a configuration example of the ramp signal generation circuit 12. As shown in FIG. 3, the ramp signal generation circuit 12 comprises a current DA conversion circuit (current DAC) 121 and an operational amplifier 122. A current according to the digital code Ci from the control circuit 14 flows in the current DAC 121. The operational amplifier 122 outputs as the ramp signal RS an output signal corresponding to a potential difference between a voltage feeding back an output signal of the operational amplifier 122 and an analog voltage corresponding to a current flowing in the current DAC 121. This linearly increases the potential of, for example, the ramp signal RS with a slope (slew rate) according to the digital code Ci. Note that the smaller the current flowing in the current DAC 121 according to the digital code Ci, the smaller the slope of the linear change in potential of the ramp signal RS becomes, and the larger the current flowing in the current DAC 121 according to the digital code Ci, the larger the slope of the linear change in potential of the ramp signal RS becomes. For example, if the current flowing in the current DAC 121 is 4i, the slope of the linear change in potential of the ramp signal RS becomes four times larger than when the current flowing in the current DAC 121 is i.

### Configuration Example of Counter 13

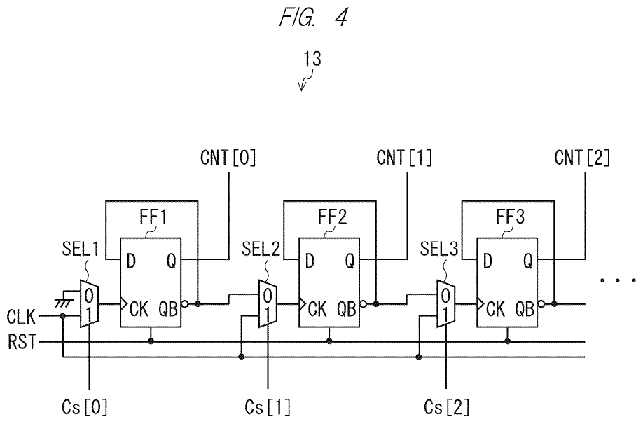

FIG. 4 is a drawing showing a configuration example of the counter 13. The counter 13 comprises a p number (p being an integer of two or more) of flip-flops FF1 to FFp and a p number of selectors SEL1 to SELp. The example of FIG. 4 shows three flip-flops FF1 to FF3 and three selectors SEL1 to SEL3.

The selector SEL1 selects and outputs either a fixed signal representing a fixed value “0” or the clock signal CLK based on a digital code Cs[0] (value of the least significant bit (first bit) of the digital code Cs). The flip-flop FF1 outputs a count value CNT[0] (value of the least significant bit (first bit) of a count value CNT) whose logic value changes synchronously with a rising edge of the output signal of the selector SEL1.

The selector SEL2 selects and outputs either an inverted signal of an output signal of the flip-flop FF1 or the clock signal CLK based on a digital code Cs[1] (value of a second bit of the digital code Cs). The flip-flop FF2 outputs a count value CNT[1] (value of a second bit of the count value CNT) whose logic value changes synchronously with a rising edge of the output signal of the selector SEL2.

The selector SEL3 selects and outputs either an inverted signal of an output signal of the flip-flop FF2 or the clock signal CLK based on a digital code Cs[2] (value of a third bit of the digital code Cs). The flip-flop FF3 outputs a count value CNT[2] (value of a third bit of the count value CNT) whose logic value changes synchronously with a rising edge of the output signal of the selector SEL3.

Likewise, the selector SELp selects and outputs either an inverted signal of an output signal of the flip-flop FFp-1 or the clock signal CLK based on a control signal S[p-1] (value of the most significant bit (pth bit) of a control signal S). The flip-flop FFp outputs a count value CNT[p-1] (value of the most significant bit (pth bit) of the count value CNT) whose logic value changes synchronously with a rising edge of the output signal of the selector SELp.

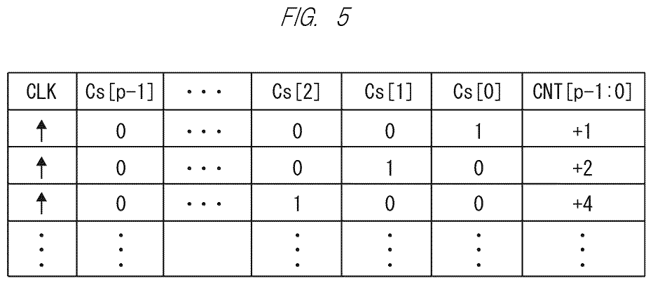

FIG. 5 is a drawing showing an example of control contents of the counter 13 controlled by the control circuit 14. As shown in FIG. 5, for example, among the p-bit wide digital codes Cs[p-1: 0], if the digital code Cs[0] (value of the first bit of the digital code Cs) is set to “1” and the others are set to “0”, the clock signal CLK is selected only by the selector SEL1 among the selectors SEL1 to SELp, and thus, the count value (hereinafter also referred to as “counter step”) that increases per count-up operation of the counter 13 is “1”.

In addition, for example, among the p-bit wide digital codes Cs[p-1:0], if the digital code Cs[1] (value of the second bit of the digital code Cs) is set to “1” and the others are set to “0”, the clock signal CLK is selected only by the selector SEL2 among the selectors SEL1 to SELp, and thus, the counter step is “2”. If the counter step is “2”, the amount of change in the count value of the counter 13 is two times larger than when the counter step is “1”.

In addition, for example, among the p-bit wide digital codes Cs[p-1:0], if the digital code Cs[2] (value of the third bit of the digital code Cs) is set to “1” and the others are set to “0”, the clock signal CLK is selected only by the selector SEL3 among the selectors SEL1 to SELp, and thus, the counter step is “4”. If the counter step is “4”, the amount of change in the count value of the counter 13 is four times larger than when the counter step is “1”.

Here, the control circuit 14 adjusts the counter step by having one of the selectors SEL1 to SELp select the clock signal CLK according to the count value of the counter 13.

### Setting Example of Register 15

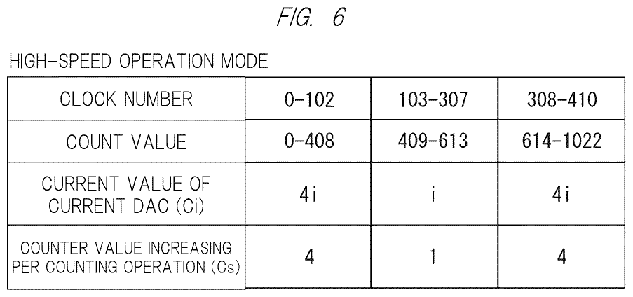

FIG. 6 is a drawing showing an example of setting contents of the register 15. For example, a plurality of combinations of a range of the count value of the counter 13 and the digital codes Ci and Cs respectively representing the slope of the linear change in the ramp signal RS (current value of the current DAC in this example) and the amount of change in the count value of the counter 13 (counter step) are stored in the register 15. In the example of FIG. 6, setting contents for the high-speed operation mode are stored in the register 15.

For example, combinations of the range of the count value “0-408” and the digital codes Ci and Cs respectively representing the current value “4i” of the current DAC and the counter step “4” are stored in the register 15 for the high-speed operation mode. In addition, combinations of the range of the count value “409-613” and the digital codes Ci and Cs respectively representing the current value “i” of the current DAC and the counter step “1” are stored in the register 15. Further, combinations of the range of the count value “614-1022” and the digital codes Ci and Cs respectively representing the current value “4i” of the current DAC and the counter step “4” are stored in the register 15.

### Operation of Semiconductor Device 1

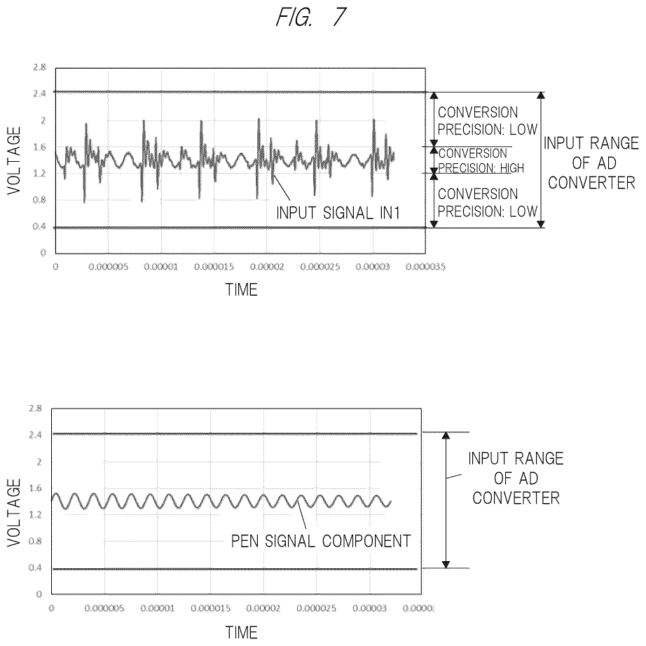

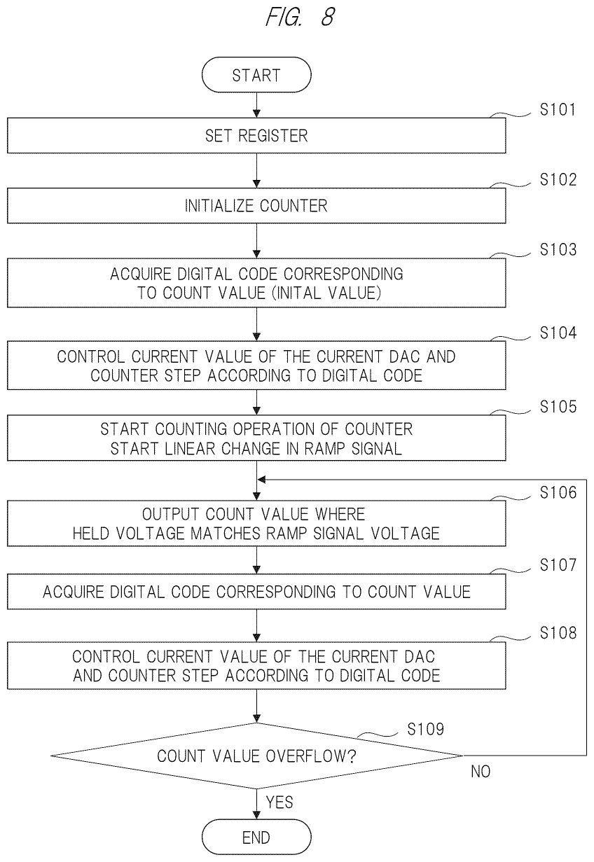

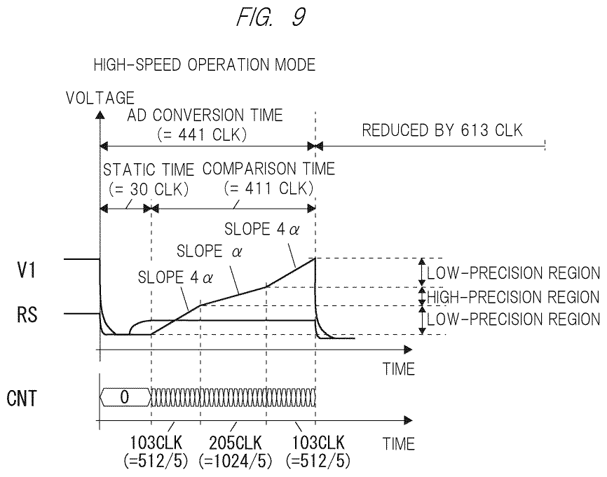

Next, an operation of the semiconductor device 1 in the high-speed operation mode will be described with reference to FIGS. 7 to 9. FIG. 7 is a drawing showing signal waveforms for the input signal IN1 and each of the pen signal components contained therein. FIG. 8 is a flowchart showing an operation of the semiconductor device 1. FIG. 9 is a timing chart showing an operation of the semiconductor device 1 in the high-speed operation mode.

Hereinafter, a flow of an AD conversion process of the input signal IN1 by the AD converter 11_1 among the AD converters 11_1 to 11_m provided in the semiconductor device 1 will be described. Note that the same can be applied to the AD conversion processes of the input signals IN2 to INm by the AD converters 11_2 to 11_m.

As shown in FIG. 7, the input signal IN1 includes a sinusoidal signal (pen signal) of a predetermined frequency in which an amplitude increases due to an antenna coil when the touch pen approaches the touch panel as well as a high-amplitude high-frequency noise component. For example, in an input range of 0.4V to 2.4V of each of the AD converters, the amplitude of the pen signal is in the range of 1.2V to 1.6V, whereas the amplitude of the high-frequency noise is in the range of 0.8V to 2V. Therefore, the semiconductor device 1 according to the present disclosure in the high-speed operation mode increases AD conversion precision in a middle region of the amplitude of the input signals IN1 to INm which is the region containing the pen signal component and is among the input range of each of the AD converters 11_1 to 11_m, while reducing the AD conversion precision at both end regions of the amplitude of the input signals IN1 to INm which are regions containing the noise components to increase AD conversion speed.

First, in the semiconductor device 1, setting of the register 15 is performed (step S101). Specifically, in the register 15, a combination of the range of the count value of the counter 13 and the digital codes Ci and Cs respectively representing the slope of the linear change in the ramp signal RS (current value of the current DAC in this example) and the amount of change in the count value of the counter 13 (counter step) is set as shown in FIG. 6.

Then, the counter 13 is initialized (step S102). Specifically, the count value of the counter 13 is initialized to “0”.

Then, the control circuit 14 acquires the digital codes Ci and Cs corresponding to the count value of the counter 13 from the register 15 (step S103). Specifically, the control circuit 14 acquires the digital codes Ci and Cs respectively representing the current value “4i” of the current DAC and the counter step “4” according to the count value “0” from the register 15.

Then, the control circuit 14 controls the current value of the current DAC 121 and the amount of change in the count value of the counter 13 (counter step) based on the acquired digital codes Ci and Cs (step S104). Specifically, the control circuit 14 controls the current value of the current DAC 121 to “4i” and controls the counter step to “4”. This allows the slope of the linear change in the ramp signal RS to be “4α” which is four times the normal value (that is, in a case where the current value of the current DAC 121 is “i”), and the count value that increases per count-up operation of the counter 13 to be “4” which is four times the normal value (that is, in a case where the counter step is “1”). Then, the control circuit 14 causes the counter 13 to start the counting operation and the ramp signal generation circuit 12 to start generation of the ramp signal RS (step S105). Thus, in a lower end region of the amplitude of the input signal IN1 which is the region containing the noise component, a high-speed and relatively low-precision AD conversion is performed. For example, AD conversion with an 8-bit precision is performed.

Here, each of the AD conversion circuits AD1 to ADn configuring the AD converter 11_1 performs a comparison between the held input voltage and the voltage of the ramp signal RS, and outputs the count value of the counter 13 at a timing where the held input voltage matches the voltage of the ramp signal RS as a portion of a result OUT1 of AD conversion (step S106).

In addition, each time the count value of the counter 13 changes, the control circuit 14 acquires the digital codes Ci and Cs corresponding to the count value from the register 15 until the count value of the counter 13 overflows (or until a stop signal for stopping the AD conversion process is received), and controls the current value of the current DAC 121 and the amount of change in the count value of the counter 13 based on the acquired digital codes Ci and Cs (steps S107, S108, and NO of S109).

For example, when the count value of the counter 13 is “409”, the control circuit 14 acquires the digital codes Ci and Cs respectively representing the current value “i” of the current DAC and the counter step “1” from the register 15. Then, the control circuit 14 controls the current value “i” of the current DAC 121 to and controls the counter step to “1” based on the acquired digital codes Ci and Cs. This allows the slope of the linear change in the ramp signal RS to be “α” which is the normal value, and the count value that increases per count-up operation of the counter 13 to be “1”. Thus, in the middle region of the amplitude of the input signal IN1 which is the region containing the pen signal component, a low-speed and high-precision AD conversion is performed. For example, an AD conversion with a 10-bit precision is performed.

Further, when the count value of the counter 13 is “614”, the control circuit 14 acquires the digital codes Ci and Cs respectively representing the current value “4i” of the current DAC and the counter step “4” from the register 15. Then, the control circuit 14 controls the current value of the current DAC 121 to “4i” and controls the counter step to “4” based on the acquired digital codes Ci and Cs. This allows the slope of the linear change in the ramp signal RS to be “4α” which is four times the normal value and the count value that increases per count-up operation of the counter 13 to be “4” which is four times the normal value. Thus, in an upper end region of the amplitude of the input signal IN1 which is the region containing the noise component, a relatively low-precision and high-speed AD conversion is performed. For example, AD conversion with an 8-bit precision is performed.

Each of the AD conversion circuits AD1 to ADn configuring the AD converter 11_1 continues to compare the held input voltage and the ramp signal RS until the count value overflows (or until the AD conversion process is stopped by the control circuit 14), and outputs the count value of the counter 13 at a timing where the held input voltage matches the voltage of the ramp signal RS as a portion of the result OUT1 of AD conversion (step S106).

Then, when the count value of the counter 13 overflows (YES of step S109), the semiconductor device 1 ends the AD conversion process by the AD converter 11_1 of the sampled input signal IN1. Note that, in a case where the semiconductor device 1 performs the AD conversion process by the AD converter 11_1 of the subsequently sampled input signal IN1, the processes of steps S101 to S109 are repeated.

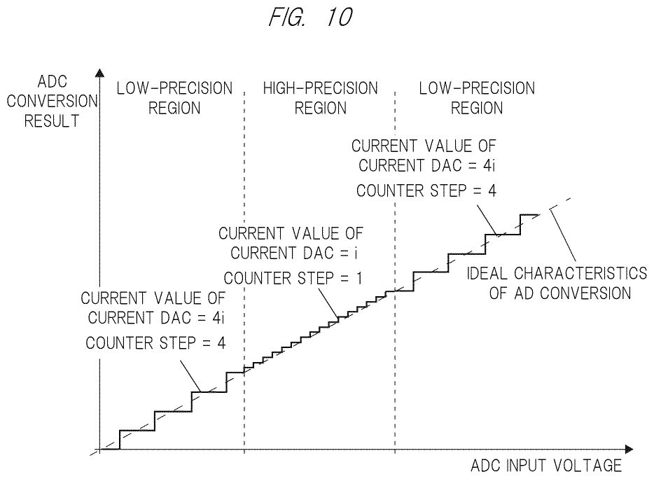

FIG. 10 is a drawing showing a relationship between the voltages of the input signal IN1 of the AD converter 11_1 and the results of AD conversion. As shown in FIG. 10, in the semiconductor device 1, as the slope of the linear change in the ramp signal RS (current value of the current DAC in this example) switches, the amount of change in the count value of the counter 13 (counter step) is switched, and thus, the result of AD conversion does not deviate from the ideal characteristics even if the AD conversion precision is switched during AD conversion.

### Comparative Example

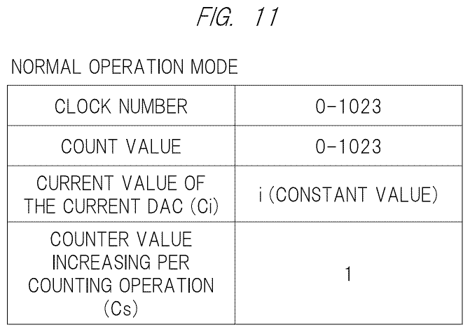

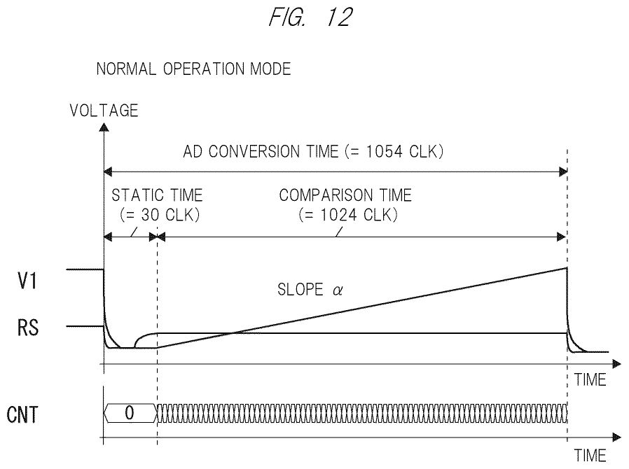

FIG. 11 is a drawing showing an example of setting contents of the register 15 in a normal operation mode. In the example of FIG. 6, setting contents for the high-speed operation mode are stored in the register 15. In contrast, in the example of FIG. 11, setting contents for the normal operation mode are stored in the register 15 as a comparative example. FIG. 12 is a timing chart showing an operation of the semiconductor device 1 in the normal operation mode.

For example, combinations of the range of the count value “0-1023” and the digital codes Ci and Cs respectively representing the current value “i” of the current DAC and the counter step “1” are stored in the register 15 for the normal operation mode.

For example, when the count value of the counter 13 is initialized to “0”, the control circuit 14 acquires the digital codes Ci and Cs respectively representing the current value “i” of the current DAC and the counter step “1” from the register 15. Then, the control circuit 14 controls the current value of the current DAC 121 to “i” and controls the counter step to “1” based on the acquired digital codes Ci and Cs. This allows the slope of the linear change in the ramp signal RS to be “α” which is the normal value, and the count value that increases per count-up operation of the counter 13 to be “1”. The setting contents are maintained until the count value of the counter 13 reaches “1023” and overflows. Thus, a high-precision AD conversion is constantly performed on the input signal IN1. In other words, a high-precision and relatively low-speed AD conversion is performed not only in the middle region of the amplitude of the input signal IN1 containing the pen signal component but also at both end regions of the amplitude of the input signal IN1 containing the noise component.

Comparing AD conversion of the AD converter 11_1 in the normal operation mode shown in FIG. 12 and AD conversion of the AD converter 11_1 in the high-speed operation mode shown in FIG. 9, it can be seen that, in the normal operation mode, an AD conversion time is 1054 clocks which is the sum of 30 clocks for a static time and 1024 clocks for a comparison time, whereas in the high-speed operation mode, the AD conversion time is 441 clocks which is the sum of 30 clocks for the static time and 411 clocks for the comparison time, thus reducing the AD conversion time by 613 clocks. In this manner, the semiconductor device 1 according to the present embodiment is configured such that, among the input range of each of the AD converters 11_1 to 11_m, the AD conversion precision is increased in the middle region of the amplitude of the input signals IN1 to INm which is the region containing the pen signal component while the AD conversion precision is reduced in both end regions of the amplitude of the input signals IN1 to INm which are regions containing the noise component to increase the AD conversion speed. Here, in the semiconductor device 1 according to the present embodiment, as the slope of the linear change in the ramp signal RS (current value of the current DAC in this example) switches, the amount of change in the count value of the counter 13 (counter step) is switched, and thus, the result of AD conversion does not deviate from the ideal characteristics even if the AD conversion precision is switched during AD conversion (see FIG. 10). This allows the semiconductor device 1 according to the present embodiment to realize a high-speed AD conversion while suppressing quality degradation. Note that realizing a high-speed AD conversion means that, for example, the number of AD conversion circuits AD1 to ADn necessary to complete AD conversion of the input signal IN1 by the AD converter 11_1 within a predetermined time can be reduced. Therefore, the semiconductor device 1 according to the present embodiment can reduce the circuit size while suppressing quality degradation of AD conversion.

### Modification of Semiconductor Device 1

The semiconductor device 1 is not limited to being applied to a touch panel, and may also be applied to, for example, a CMOS image sensor. In the CMOS image sensor, the count value of the counter 13 at a timing where a pixel signal (corresponding to the input voltage V1 and the like) indicating a potential according to the amount of light received by a pixel matches the ramp signal RS is output as a digital signal (corresponding to the digital signal O1 and the like) corresponding to the pixel signal.

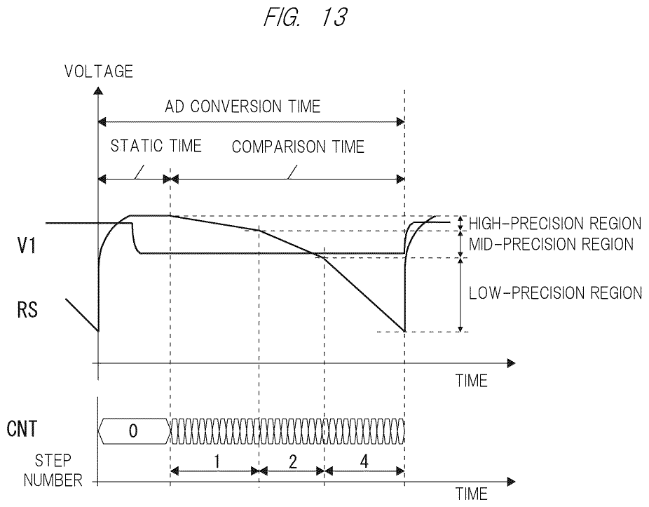

Here, for AD conversion of the pixel signal, the lower the luminance of the pixel signal, the higher the sensitivity is required. Therefore, as shown in a timing chart of FIG. 13, the semiconductor device 1 performs a high-precision AD conversion with about a 10-bit precision for a low-luminance pixel signal, performs a medium-precision AD conversion with about a 9-bit precision for a medium-luminance pixel signal, and performs a high-speed AD conversion with a relatively low precision of about an 8-bit precision for a high-luminance pixel signal. Here, in the semiconductor device 1, the slope of the linear change in the ramp signal RS (current value of the current DAC in this example) and the amount of change in the count value of the counter 13 (counter step) are switched, such that the result of AD conversion does not deviate from the ideal characteristics even if the AD conversion precision is switched during AD conversion. This allows the semiconductor device 1 according to the present embodiment to realize a high-speed AD conversion while suppressing quality degradation. Note that realizing a high-speed AD conversion means that, for example, the number of AD conversion circuits (corresponding to AD1 to ADn) necessary to complete AD conversion of a predetermined number of pixel signals within a predetermined time can be reduced. Therefore, the semiconductor device 1 according to the present embodiment can reduce the circuit size while suppressing quality degradation of AD conversion. Note that, in the example of FIG. 13, the ramp signal RS is decreasing linearly.

### Second Embodiment

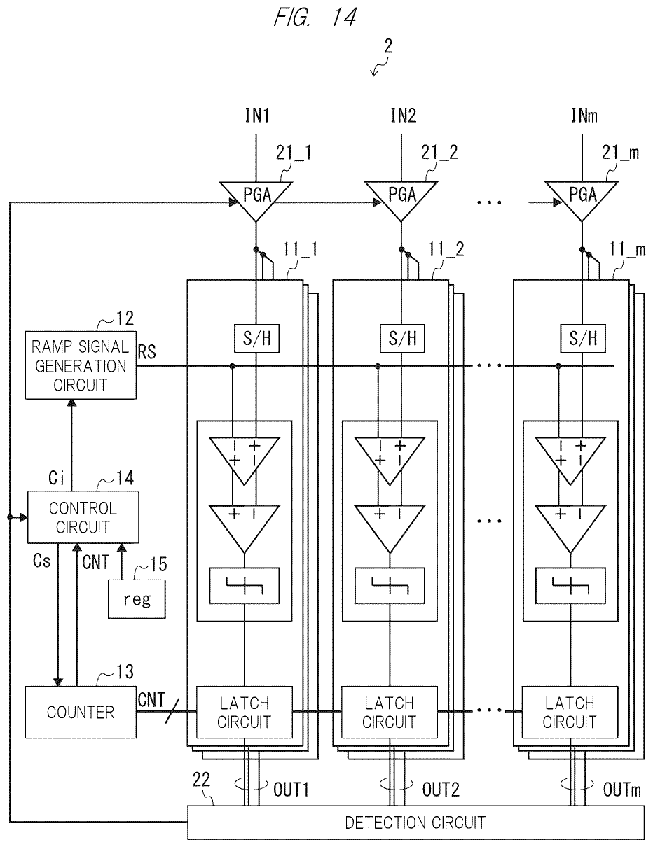

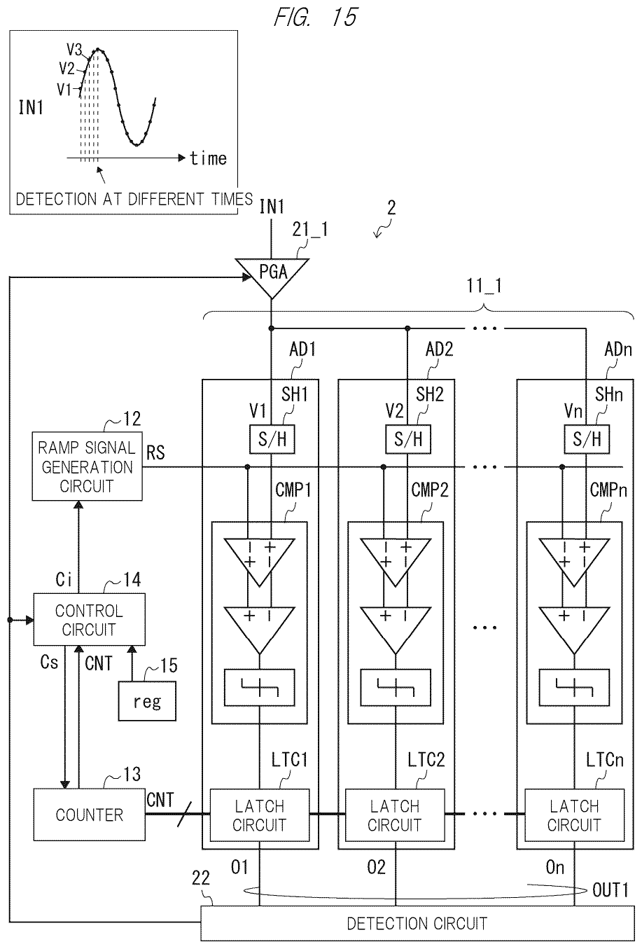

FIG. 14 is a block diagram showing a configuration example of a semiconductor device 2 according to a second embodiment. In addition, FIG. 15 is a block diagram showing a configuration example of a portion of the semiconductor device 2. The example of FIG. 15 shows a configuration example of the AD converter 11_1 among the AD converters 11_1 to 11_m. The AD converters 11_2 to 11_m have the same configuration as the AD converter 11_1 with the exception of the input signals IN2 to INm being respectively input instead of the input signal IN1, and thus, descriptions thereof are omitted as appropriate.

The semiconductor device 2 differs from the semiconductor device 1 in that it further comprises programmable gain amplifiers (PGAs) 21_1 to 21_m and a detection circuit 22. Other configurations of the semiconductor device 2 are the same as those of the semiconductor device 1, and thus, descriptions thereof are omitted as appropriate.

The detection circuit 22 first detects waveform amplitudes of the results OUT1 to OUTm of AD conversion of each of the AD converters 11_1 to 11_m. These waveform amplitudes include noise components. The detection circuit 22 further decomposes the results OUT1 to OUTm of AD conversion of each of the AD converters 11_1 to 11_m into frequency components and outputs them as discrete Fourie transform (DFT) results.

The PGAs 21_1 to 21_m are respectively provided in a front stage of the AD converters 11_1 to 11_m. The PGAs 21_1 to 21_m adjust the amplitudes of the input signals IN1 to INm input to the AD converters 11_1 to 11_m to be optimal based on waveform amplitude information detected by the detection circuit 22. Specifically, the PGAs 21_1 to 21_m adjust the amplitudes of the input signals IN1 to INm input to the AD converters 11_1 to 11_m such that the amplitudes are large as possible within the input range of the AD converters 11_1 to 11_m. The AD converters 11_1 to 11_m each perform AD conversion of the input signals IN1 to INm having amplitudes adjusted by the PGAs 21_1 to 21_m.

Based on the amplitudes of the predetermined frequency components (specifically, pen signal frequency components) extracted by the detection circuit 22, the control circuit 14 adjusts the setting contents of the register 15 (that is, the digital code and the range of the count value of the counter 13 corresponding to the digital code). In other words, the control circuit 14 adjusts the range in which the high-precision AD conversion is performed and its AD conversion precision such that the pen signal component contained in the input signal is AD-converted accurately and with high-precision.

This allows the semiconductor device 2 according to the present embodiment to achieve the same degree of effectiveness as the semiconductor device 1. In addition, the semiconductor device 2 according to the present embodiment can perform AD conversion of a desired frequency component signal more accurately by feeding back the result of the detection circuit 22 to the control circuit 14 to adjust the setting contents of the register 15 or to adjust a gain of the PGA. In the present embodiment, a case where the result of the detection circuit 22 is fed back to the PGAs 21_1 to 21_m and the control circuit 14 is described. However, the invention is not limited to such a configuration, and the result may be fed back only to one of the PGAs 21_1 to 21_m and the control circuit 14.

In the foregoing, the invention made by the present inventors has been concretely described on the basis of the embodiments. However, it is needless to say that the present invention is not limited to the foregoing embodiments, and various modifications and alterations can be made within the scope of the present invention.

It is possible for the present disclosure to recognize a portion of or all of the processes of each of the semiconductor devices 1 and 2 by causing a CPU to perform a computer program.

The above-described program includes a set of instructions (or software code) that, when read into a computer, causes the computer to perform one or more of the functions described above. The program may be stored in a non-transitory computer-readable medium or in an entity storage medium. By way of example but not limiting, the computer-readable medium or entity storage medium may be random-access memory (RAM), read-only memory (ROM), flash memory, solid-state drive (SSD) or any other memory technology, CD-ROM, digital versatile disc (DVD), Blu-ray (registered trademark) disc or any other optical disc storage, magnetic cassette, magnetic tape, magnetic disk storage or any other magnetic storage device. The program may be transmitted on a transitory computer-readable medium or a communication medium. By way of example but not limiting, the transitory computer-readable medium or communication medium includes electrical, optical, acoustic, or any other form of propagation signals.

What is claimed is:

1. A semiconductor device comprising:
a plurality of sample-and-hold circuits each configured to sample voltages of an analog input signal at different timings and hold them as a plurality of input voltages;
a ramp signal generation circuit configured to generate a ramp signal whose potential changes linearly;
a counter configured to trigger a start of the linear change in the ramp signal and perform a counting operation;
a plurality of comparison circuits each configured to compare each of the plurality of input voltages and a voltage of the ramp signal;
a plurality of latch circuits each configured to output a count value of the counter at a timing where each of the plurality of input voltages matches the voltage of the ramp signal as a plurality of digital signals respectively corresponding to the plurality of input voltages; and
a control circuit configured to control a slope of the linear change in the ramp signal and the amount of change in the count value of the counter according to the count value of the counter,
wherein the plurality of digital signals are output as a result of AD conversion of the input signal.

2. The semiconductor device according to claim 1,
wherein, when the slope of the linear change in the ramp signal is switched from a first slope to a second slope having a smaller slope than the first slope, the control circuit switches the amount of change in the count value of the counter from a first amount of change to a second amount of change having a smaller amount of change than the first amount of change, and when the slope of the linear change in the ramp signal is switched from the second slope to the first slope, the control circuit switches the amount of change in the count value of the counter from the second amount of change to the first amount of change.

3. The semiconductor device according to claim 1,
wherein the control circuit is configured to output a control signal of a digital code according to the count value of the counter, and
wherein the ramp signal generation circuit includes:
a DA conversion circuit configured to convert the digital code of the control signal into an analog signal; and
an amplifier circuit configured to output the ramp signal according to a potential difference between an output signal of the DA conversion circuit and a feedback signal of the ramp signal.

4. The semiconductor device according to claim 1 including:
a first selector configured to select and output either a fixed signal representing a fixed value or a clock signal;
a first flip-flop configured to output a value of a first bit which is a value of the least significant bit among the plurality of bits configuring the count value whose logic value changes synchronously with a rising edge of an output signal of the first selector;
second to m^{th} (m being an integer of two or more) selectors each configured to select and output either the clock signal or an output signal of a flip-flop corresponding to the first to m^{th} flip-flops;
second to nth flip-flops each configured to output a value of a second to nth (n being m+1) bit among the plurality of bits configuring the count value whose logic value changes synchronously with a rising edge of a respective output signal of the second to m^{th} selectors;
wherein the control circuit is configured to cause one of the first to nth selectors to select the clock signal according to the count value of the counter.

5. The semiconductor device according to claim 1, further comprising
a register configured to store a plurality of combinations of a range of the count value of the counter and digital codes respectively representing the slope of the linear change in the ramp signal and the amount of change in the count value of the counter,
wherein the control circuit is configured to control the slope of the linear change in the ramp signal and the amount of change in the count value of the counter based on the digital codes extracted from the register according to the count value of the counter.

6. The semiconductor device according to claim 5, further comprising
a detection circuit configured to decompose the result of AD conversion into a frequency component and output it as a discrete Fourie transform (DFT) result,
wherein the control circuit is configured to adjust the digital codes and the range of the count value of the counter corresponding to the digital codes based on an amplitude of the predetermined frequency component extracted by the detection circuit.

7. The semiconductor device according to claim 6,
wherein the detection circuit is configured to further detect a waveform amplitude of the result of AD conversion, and
wherein the semiconductor device further comprises a plurality of programmable gain amplifiers configured to adjust an amplitude of the input signal based on the waveform amplitude detected by the detection circuit.

8. A control method of a semiconductor device including:
sampling voltages of an analog input signal at different timings and respectively holding them as a plurality of input voltages;
triggering a start of a linear change in a ramp signal whose potential changes linearly and starting a counting operation of a counter; and
outputting a count value of the counter at a timing where each of the plurality of input voltages matches a voltage of the ramp signal as a result of AD conversion of the input signal,
wherein a slope of the linear change in the ramp signal and the amount of change in the count value of the counter are controlled according to the count value of the counter.

9. The control method according to claim 8,
wherein, in controlling the slope of the linear change in the ramp signal and the amount of change in the count value of the counter, when the slope of the linear change in the ramp signal is switched from a first slope to a second slope having a smaller slope than the first slope, the amount of change in the count value of the counter is switched from a first amount of change to a second amount of change having a smaller amount of change than the first amount of change, and when the slope of the linear change in the ramp signal is switched from the second slope to the first slope, the amount of change in the count value of the counter is switched from the second amount of change to the first amount of change.

10. A control program configured to cause a computer to execute:
a process of sampling voltages of an analog input signal at different timings and respectively holding them as a plurality of input voltages;
a process of triggering a start of a linear change in a ramp signal whose potential changes linearly and starting a counting operation of a counter; and
a process of outputting a count value of the counter at a timing where each of the plurality of input voltages matches a voltage of the ramp signal as a result of AD conversion of the input signal,
wherein the control program further causes the computer to execute a process of controlling a slope of the linear change in the ramp signal and the amount of change in the count value of the counter according to the count value of the counter.

11. The control program according to claim 10,
wherein, in the process of controlling the slope of the linear change in the ramp signal and the amount of change in the count value of the counter, when the slope of the linear change in the ramp signal is switched from a first slope to a second slope having a smaller slope than the first slope, the amount of change in the count value of the counter is switched from a first amount of change to a second amount of change having a smaller amount of change than the first amount of change, and when the slope of the linear change in the ramp signal is switched from the second slope to the first slope, the amount of change in the count value of the counter is switched from the second amount of change to the first amount of change.
